(19) United States
(12) Patent Application Publication
(10) Pub. No.: US 2013/0264949 A1
(43) Pub. Date: Oct. 10, 2013

(54) SENSOR COMPRISING AT LEAST A VERTICAL DOUBLE JUNCTION PHOTODIODE, BEING INTEGRATED ON A SEMICONDUCTOR SUBSTRATE AND CORRESPONDING INTEGRATION PROCESS

(71) Applicant: STMICROELECTRONICS S.R.L., Agrate Brianza (IT)

(72) Inventors: Salvatore Leonardi, Aci S. Antonio (IT); Maria Eloisa Castagna, Catania (IT); Anna Muscara, Patti (IT)

(21) Appl. No.: 13/802,081

(22) Filed: Mar. 13, 2013

Related U.S. Application Data
(62) Division of application No. 12/649,248, filed on Dec. 29, 2009.

(30) Foreign Application Priority Data
Dec. 31, 2008 (IT) MI2008A002363

(51) Int. Cl. H01L 31/11; H05B 37/02

(52) U.S. Cl. CPC H01L 31/11; H05B 37/0218
USPC 315/158; 250/216; 250/206

(57) ABSTRACT

An embodiment relates to a sensor being integrated on a semiconductor substrate and comprising at least a vertical double-junction photodiode, in turn comprising at least one first and one second p-n junction formed in said semiconductor substrate, as well as at least an anti-reflection coating formed on said photodiode. Said at least one anti-reflection coating comprises at least one first and one second different anti-reflection layer being suitable to obtain a responsivity peak in correspondence with a predetermined wavelength of an incident optical signal on said sensor. An embodiment also relates to an integration process of such a sensor, as well as to an ambient light sensor made by means of such a sensor.

### RELATED APPLICATION DATA

The instant application is a Divisional of U.S. patent application Ser. No. 12/649,248 (Attorney Docket No. 2110-318-03 (08-CT-132); and is related to commonly assigned and copending U.S. patent application Ser. No. 12/649,256 (Attorney Docket No. 2110-319-03 (06-CT-465)), entitled RADIATION SENSOR WITH PHOTODIODES BEING INTEGRATED ON A SEMICONDUCTOR SUBSTRATE AND CORRESPONDING INTEGRATION PROCESS, filed on even date herewith, which application is incorporated herein by reference in its entirety.

### PRIORITY CLAIM

The instant application claims priority to Italian Patent Application No. M12008A002363, filed Dec. 31, 2008, which application is incorporated herein by reference in its entirety.

### TECHNICAL FIELD

An embodiment of the present disclosure relates to a radiation sensor with photodiodes being integrated on a semiconductor substrate.

More specifically, an embodiment of the disclosure relates to a radiation sensor being integrated on a semiconductor substrate and comprising at least one first and one second photodiode comprising at least one first and one second p-n junction formed in said semiconductor substrate, as well as at least one first and one second anti-reflection coating formed on said first and second photodiodes.

An embodiment of the disclosure also relates to an integration process of such a radiation sensor with photodiodes being integrated on a semiconductor substrate.

An embodiment of the disclosure relates particularly, but not exclusively, to a photodiode sensor being integrated on a silicon semiconductor substrate suitable to form an ambient light sensor and the following description is made with reference to this field of application for convenience of illustration only.

### BACKGROUND

The term radiation sensor or photodetector is meant to identify devices being suitable to detect optical signals, particularly light, and to convert them to electrical signals. Usually, these devices exploit the absorption coefficient of a specific material being used to manufacture them.

In the case of semiconductor devices, optical-signal photons are absorbed by silicon creating electron-hole pairs (based on the intrinsic transition phenomenon) if the energy of such photons is higher or equal to the energy of the silicon forbidden band (equal to 1.1 eV in the crystalline silicon case).

In case the energy of a photon is not sufficient, the same will be absorbed anyway if there are available energy states in the band, particularly due to impurities or defects. This is the case of extrinsic transition.

The number of photons absorbed by a particular material at the distance Δx is given by: αΦ(x)Δx, wherein α is the absorption coefficient of such a material and Φ is the incident photon flux on the material.

Absorption coefficients are a function of the wavelength. In the case of semiconductor materials, these coefficients can range from 10³ to 10⁸ with wavelengths λ ranging from approximately 0.2 to 1.8 μm.

Radiation sensors are used in different applications, for example to form ambient light sensors or ALS (acronym “Ambient Light Sensor”). In this case, the radiation sensor is commonly formed by means of silicon photodiodes, i.e. integrated on a semiconductor.

In particular, an ambient light sensor is a device being designed to detect the ambient light intensity, in a way resembling as much as possible the human eye sensitivity. Such a device is commonly used to adjust the brightness of electronic devices in function of ambient light conditions (backlight setting), for example to adjust the display backlight, the display or numeric keypad brightness, the night or home lighting, etc, all in order to let the human eye see the electronic device being concerned in the most possible pleasant and effective way.

In particular, the use of ambient light sensors allows an even more than 50% energy saving for the system in which they are assembled (so-called “power saving” function), all optimizing the brightness of such a system (“autodimming” function) in function of the human eye perception required by the particular ambient condition.

As previously mentioned, photodiodes, but also phototransistors, being silicon-integrated are low-cost devices usually used to form a radiation sensor, particularly in the case of ambient light sensors.

An integrated photodiode is formed by a reverse-biased p-n junction formed in a semiconductor substrate. More particularly, an asymmetrically doped p-n junction is used, wherein the p region, i.e. the acceptor-doped region, is much more highly doped than the n region doped with donor atoms, to improve the photodiode response in some regions of the visible spectrum.

In fact, photodetection mainly concerns two regions of the photodiode structure: a surface region, whereon light is incident, and an absorbent material region, particularly silicon, wherein the p-n junction is formed.

In order to be able to run, the photodiode, and particularly the surface region thereof, should be exposed to light. In this surface region, materials tending to reflect the light, particularly metals, should be then avoided as much as possible, whereas anti-reflection materials are conveniently used to absorb as much light as possible of the incident radiation and to reduce reflected light to a minimum.

In this way, the integrated photodiode, when being hit by a light signal, generates electron-hole pairs within a diffusion length, in the space charge region the pairs are split by an appropriate electrical field and they contribute to the photocurrent being generated. For this reason the space charge region should be very wide.

Electrons coming out of the n region are collected by an appropriate generator and injected in the p region, wherein they recombine with the photogenerated holes (in equal number). The photocurrent Ip being thus created in the photodiode is proportional to the number of electron-hole pairs being generated and thus to the number of photons of the optical signal hitting the photodiode itself. In other words, a photodiode outputs a current being a function of the intensity of the light inciding thereon and, by measuring it, it is thus possible to detect the lighting for example of the environment wherein the photodiode is placed and thus consequently adjust the lighting conditions of the electronic device equipped with an ambient light sensor formed by these photodiodes.

It can be verified that one of the important parameters for a photodiode of this type is the quantum efficiency, i.e. the number of pairs generated for each incident photon, equal to:

$$η = ( \frac{{I}_{p}}{q} ) {( \frac{{P}_{opt}}{hv} )}^{- 1}$$

wherein:

η is the quantum efficiency

Ip is the photocurrent that flows through the photodiode;

q is the charge of an electron

Popt is the incident optical power

h is the Planck's constant

v is the frequency of the incident optical signal

The photodiode responsivity is also defined as the ratio between the photocurrent Ip and the incident optical power Popt.

FIG. 1 shows (normalized) responsivity curves experimentally obtained in the silicon photodiodes case, particularly with surface junction (curve R1) and deep junction (curve R2), being compared with the optical response of the human eye (curve ER), which is, as well known, sensitive only to radiation having a wavelength approximately comprised between 400 and 700 nm.

It is thus possible to shift the peak of the silicon photodiode responsivity curve by changing the depth of the p-n junction forming it with respect to the semiconductor surface wherein this photodiode is formed. In general, it can be verified that it is possible to change this peak by varying the structural features of the p-n junction forming the photodiode. Nevertheless it may be difficult to impossible to obtain a responsivity curve coinciding with the human eye response (curve ER in FIG. 1), particularly by zeroing the photodiode response to ultraviolet radiations (UV) and in the near infrared (IR), i.e. approximately below 400 nm and above 700 nm.

To approach this result, one of the most used solutions in ambient light sensors presently on sale is to generate the current signal coming from two p-n junctions (i.e. from two different photodiodes) with different responsivity, as schematically shown in FIGS. 2A-2C. In particular the optical signals of these photodiodes with different responsivity PH1 and PH2 (FIG. 2A) are subtracted (FIG. 2B) obtaining a combined responsivity PHc of the type shown in FIG. 2C.

It is worth remembering that also in this case the different responsivity of the two photodiodes is usually obtained by differentiating the depth of the p-n junction forming them. This is also the case of a double-junction photodiode.

Although advantageous under several aspects, this known solution has a drawback of requiring precise and different steps of doping the integrated radiation sensor comprising the two photodiodes to obtain the required different-depth p-n junctions. Thus, new implants may be implemented in the technology through which these photodiodes are to be formed.

### SUMMARY

An embodiment of the present disclosure is a photodiode radiation sensor, having such structural and functional features so as not to require different-depth junctions, thus overcoming at least some of the limitations and drawbacks still limiting the devices formed according to the prior art and forming a sensor with a responsivity resembling as much as possible the human eye response.

An embodiment of the present disclosure is to use a vertical double-junction photodiode and a double-layer anti-reflection coating thus obtaining a sensor being particularly suitable for the application as an ambient light sensor having a responsivity peak in correspondence with a human eye sensitivity peak, without requiring a particular processing circuitry for the photocurrents coming from the vertical double-junction photodiode.

In an embodiment a sensor is integrated on a semiconductor substrate and comprising at least one vertical double-junction photodiode, comprising in turn at least one first and one second p-n junction formed in said semiconductor substrate, as well as at least one anti-reflection coating formed on said photodiode (PHD), wherein said at least one anti-reflection coating comprises at least one first and one second different anti-reflection layer suitable to obtain a responsivity peak in correspondence with a predetermined wavelength of an optical signal being incident on said sensor.

Conveniently, said responsivity peak may correspond to a human eye sensitivity peak, said predetermined wavelength being equal to approximately 540 nm.

According to an embodiment of the disclosure, said first anti-reflection layer may be formed by a dielectric layer being as thick as half said predetermined wavelength and said second anti-reflection layer may be formed by a dielectric layer being as thick as a fourth of said predetermined wavelength.

Conveniently, said first anti-reflection dielectric layer may be silicon oxide and said second anti-reflection dielectric layer may be silicon nitride.

According to an embodiment of the disclosure, said photodiode may be formed in a stacked configuration in said semiconductor substrate having a first doping type by means of a well having a second doping type and an implant formed within said well and having said first doping type, said implant and said well forming said first junction and said well and semiconductor substrate forming said second junction of said vertical double-junction photodiode.

Conveniently, said sensor may comprise first and second contact structures contacting said well and said implant respectively, and formed in an alternate structure of intermetal dielectric layers.

In an embodiment, an integration process of a sensor in a multilayer structure comprising a semiconductor substrate and an alternate structure of intermetal dielectric layers, of the type comprising the steps of:

forming in said semiconductor substrate at least one first and one second pn junction, suitable to form at least one vertical double-junction photodiode;

wherein it further comprises the steps of:

removing said intermetal dielectric layers in correspondence with at least one opening suitable to expose a surface of said semiconductor substrate in correspondence with said double junction,

depositing a first anti-reflection dielectric layer covering at least said surface; and

depositing on said first anti-reflection dielectric layer a second anti-reflection dielectric layer to form a double-layer anti-reflection coating suitable to obtain for the photodiode a responsivity peak in correspondence with a predetermined wavelength of an optical signal being incident on said sensor.

According to an embodiment of the disclosure, said deposition step of said first anti-reflection dielectric layer may comprise a deposition step of a dielectric layer being as thick as half said predetermined wavelength and said deposition step of said second anti-reflection layer comprise a deposition step of a dielectric layer being as thick as a fourth of said predetermined wavelength.

Conveniently, said deposition step of said first anti-reflection dielectric layer may comprise a deposition step of a silicon oxide layer and said deposition step of said second anti-reflection layer may comprise a deposition step of a silicon nitride layer.

Further according to an embodiment of the disclosure, said step of forming in said semiconductor substrate at least one first and one second pn junction of said photodiode may comprise the steps of:

forming in said semiconductor substrate of a first doping type at least one well of a second doping type; and

forming in said well an implant of said first doping type,

said implant and said well forming said first junction and said well and said semiconductor substrate forming said second junction of said photodiode.

Conveniently, the process may further comprise an etching step of said first and second anti-reflection dielectric layers and of an upper passivation layer in correspondence with said contact structures in order to form appropriate connection openings to said contact structures.

Furthermore, said removal step of said intermetal dielectric layers may comprise an etching chosen between a dry, wet or dry and wet etching.

Said removal step of said intermetal dielectric layers may also comprise a combined dry and wet etching in order to obtain for said opening substantially perpendicular walls with respect to said semiconductor substrate surface.

According to an embodiment of the disclosure, said removal step of said intermetal dielectric layers may comprise an etching step using a layer as a stopping layer for completely covering an active area of said sensor above a first dielectric layer, said removal step being suitable to expose a surface of said stopping layer in correspondence with said double junction.

Conveniently, the process may further comprise a dry etching step of said stopping layer conveniently removing it without size losses, and a wet etching step of said first underlying dielectric layer being suitable to expose said semiconductor substrate surface in correspondence with said double junction.

The process may further comprise a step of forming contact structures for the electrical connection of said double junction, in an alternate structure of intermetal dielectric layers.

In fact, in order to obtain for the so integrated sensor a response corresponding to the one of an ambient light sensor, a current may be picked up from the superficial junction.

Finally, in an embodiment an ambient light sensor comprises at least a sensor of the above-indicated type.

### BRIEF DESCRIPTION OF THE DRAWINGS

Features and advantages of one or more embodiments of a sensor and integration process will be apparent from the following description given by way of non limiting example with reference to the annexed drawings.

In the drawings:

FIG. 1 schematically shows (normalized) responsivity curves experimentally obtained for silicon photodiodes formed according to the prior art, compared with the human eye response;

FIGS. 2A-2C schematically show a responsivity composition of two silicon photodiodes formed according to the prior art;

FIG. 3 schematically shows a vertical double-junction photodiode sensor formed according to an embodiment of the disclosure;

FIG. 4 shows the transmittancy spectrum of an oxide/nitride double-layer anti-reflection coating according to an embodiment of the disclosure;

FIG. 5 shows the responsivity patterns obtained by a sensor comprising a photodiode equipped with an anti-reflection coating composed only by an oxide and by a double-layer anti-reflection coating according to an embodiment of the disclosure, respectively;

FIGS. 6A and 6B show the experimental data of an embodiment of a sensor formed by means of p-n junctions in HCMOS4TZ technology, with an oxide anti-reflection coating and an oxide/nitride anti-reflection layer respectively;

FIG. 7 schematically shows responsivity curves concerning only surface junctions of a vertical double-junction photodiode comprised in the sensor according to an embodiment of the disclosure in comparison with the human eye response;

FIG. 8 schematically shows responsivity curves concerning only surface junctions of a vertical double-junction photodiode comprised in the sensor according to an embodiment of the disclosure and equipped with an anti-reflection layer, in comparison with the human eye response;

FIGS. 9A to 9C schematically show the sensor according to an embodiment of the disclosure in different steps of its integration process, according to an embodiment thereof;

FIGS. 10A and 10D schematically show the sensor according to an embodiment of the disclosure in different steps of its integration process, according to an embodiment thereof; and

FIG. 11 schematically shows the percent error of a photocurrent obtained by a sensor according to an embodiment of the disclosure by lighting it up by means of a fluorescent lamp and an incandescent lamp respectively.

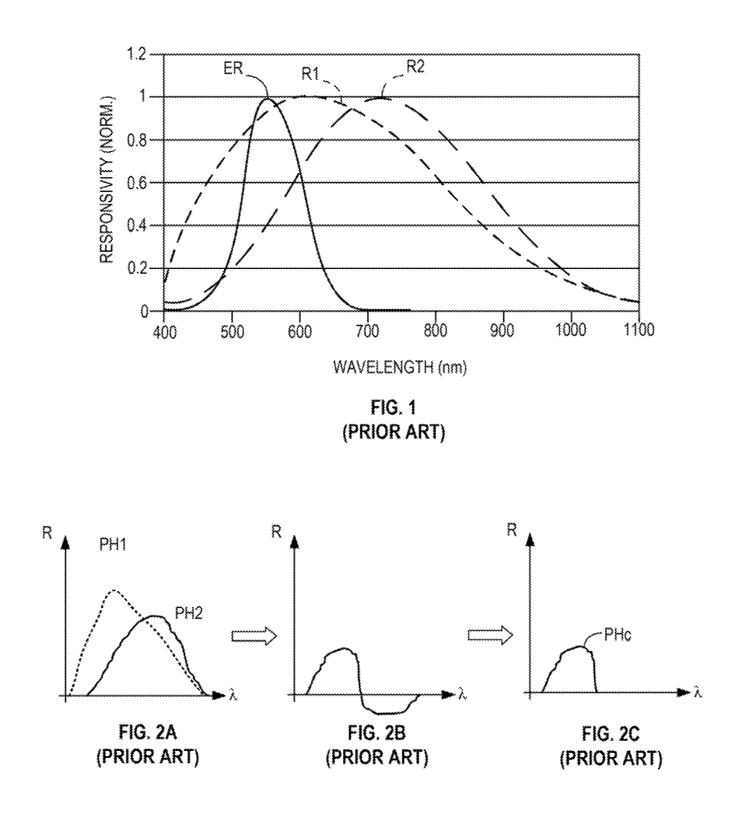

### DETAILED DESCRIPTION

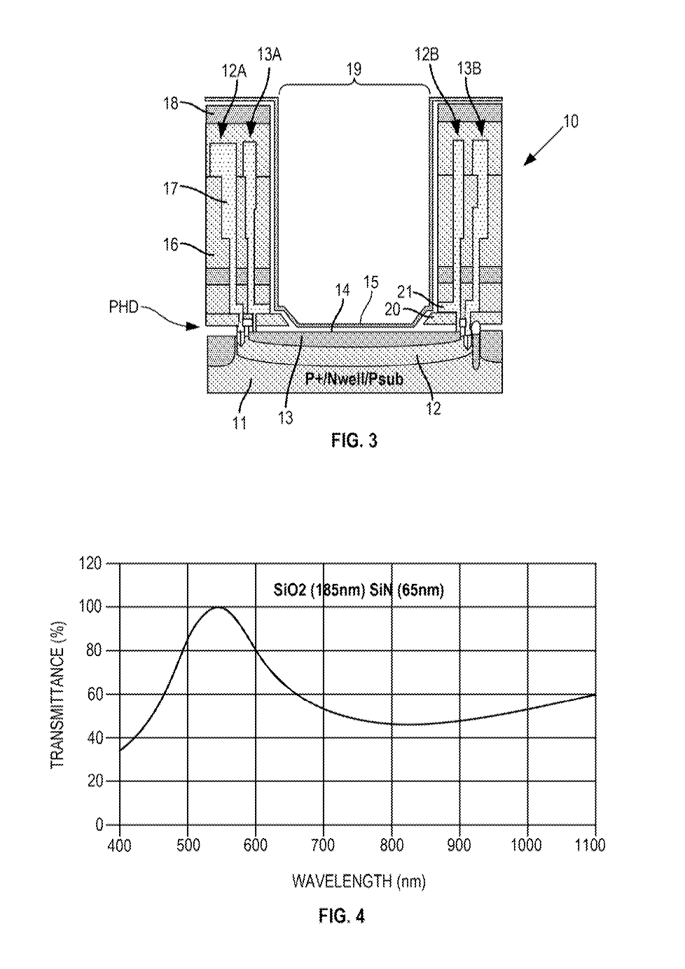

With reference to the drawings, and particularly to FIG. 3, a radiation sensor or, in short, a sensor 10 is described, being integrated on a semiconductor substrate 11 and comprising a vertical double-junction photodiode PHD.

More particularly, according to an embodiment of the disclosure, the vertical double-junction photodiode PHD is formed in the semiconductor substrate 11 of a first conductivity type by an implant of the same conductivity type formed within a well with an opposed conductivity.

In the example shown in the figure, the semiconductor substrate 11 is of the P type and it comprises a well 12 of the N type (Nwell) wherein an implant 13 of the P+ type is formed.

Should the technology use a substrate of the N type, it is possible to form the vertical double-junction photodiode PHD by means of an implant N+ formed within a P well.

According to an embodiment of the disclosure, as it will be apparent in the following description, the standard passivation of the technology is thus completely etched and removed by the photodiode PHD before depositing dielectric layers forming an anti-reflection coating for this photodiode PHD.

According to an embodiment of the disclosure, the sensor 10 comprises a vertical double-junction photodiode PHD being integrated on the semiconductor substrate 11, for example of the p type (P sub) and comprising an N well 12 formed in this semiconductor substrate 11, as well as an implant of the P+ type 13 formed within the N well 12. In substance, the implant of the P+ type 13 and the N well 12 form a first junction, while the N well 12 and the semiconductor substrate 11 form a second junction of the vertical double-junction photodiode PHD.

In this case, by conveniently biasing the sensor 10 by means of first and second contact structures 12A, 12B and 13A, 13B contacting the N well 12 and the P+ implant 13, respectively, it is possible to distinguish the photocurrents of the single junctions, as well as acquire the photocurrent deriving from the contribution of both junctions, i.e. of the P+/N well/P sub stacked structure. The first and second contact structures 12A, 12B and 13A, 13B are formed in an alternate structure of intermetal dielectric layers 16, as it will be explained in the following description. It is worth noting that this alternate structure of intermetal dielectric layers 16 may be a standard structure of the integration technology.

It may be possible to form the sensor 10 on a semiconductor substrate of the N type by means of a N+ implant formed within a P well provided in this semiconductor substrate with a N+/P well/N sub stacked structure.

Further according to an embodiment of the disclosure, the first and second anti-reflection layers 14 and 15 are conveniently chosen in order to obtain for the vertical double-junction photodiode PHD a responsivity peak in correspondence with a predetermined wavelength λ, in particular being equal to approximately 540 nm, i.e. in correspondence with the sensitivity peak of the human eye.

One may limit the losses due to the incident electromagnetic radiation reflection on the surface of a sensor 10 by integrating surface anti-reflection layers.

These anti-reflection layers may be chosen so as to have an optical thickness corresponding to a fourth of the wavelength λ of the visible light, so as to have a maximum transmission at a peak wavelength λp of the desired responsivity.

In particular, FIG. 4 shows the transmittancy curve concerning a pair of oxide and nitride layers.

In this case the transmittancy indicates the percentage of light which may be absorbed by the sensor 10, taking into consideration the quantity reflected by the surface thereof and the one in case absorbed by the anti-reflection layers comprised therein.

In particular it may be observed that the transmittancy of such an oxide/nitride double-layer coating has a peak at approximately 540 nm and a half-height amplitude of about 200 nm, features which are similar to the human eye response.

Moreover it may be observed that the anti-reflection layers have a low transmittancy in the ultraviolet (UV) because of the oxide layer absorption in this region. On the contrary in the visible range the transmittancy keeps between 80 and 95%. The choice of the oxide layer thickness to be used depends on the final application of the sensor 10, although it does not considerably weigh on the responsivity shape, but rather on the generated photocurrent intensity.

Moreover it is worth noting that the transmittancy curve of FIG. 4, concerning an embodiment of a silicon oxide/nitride double-layer coating, also may correspond to any other layer or film having a low absorption, such as for example ZnO, SiN, MgS, etc. . . . in the wavelength range being considered.

According to an embodiment of the disclosure, the use of a double anti-reflection layer deposited on the vertical double-junction photodiode PHD allows the responsivity thereof to be deeply changed.

In particular, in an embodiment of the sensor 10, the vertical double-junction photodiode PHD comprises a first anti-reflection layer 14 made of silicon oxide with a thickness of approximately λ/2n (i.e., approximately equal to half the wavelength λ=540 nm corresponding to 1900 A where n is the approximate index of refraction of the indicated materials) overlapped by a second anti-reflection layer 15 made of silicon nitride (SiN) with a thickness of approximately λ/4n in order to form the double-layer anti-reflection coating 9. It may be possible to use different anti-reflection layers, i.e., not necessarily made of silicon oxide and nitride, but generally formed by dielectric layers with a thickness of approximately λ/2n and approximately λ/4n, respectively.

The transmittancy spectrum of this double-layer anti-reflection coating (simulated as a silicon oxide-nitride pair deposited on a silicon semiconductor substrate), as shown in FIG. 4, shows a considerable transmittancy increase in the visible range.

More in detail, the double-layer anti-reflection coating according to an embodiment of the disclosure has a transmittancy peak at λ≈540 nm and a half-height amplitude of about 200 nm, features being similar to the human eye response.

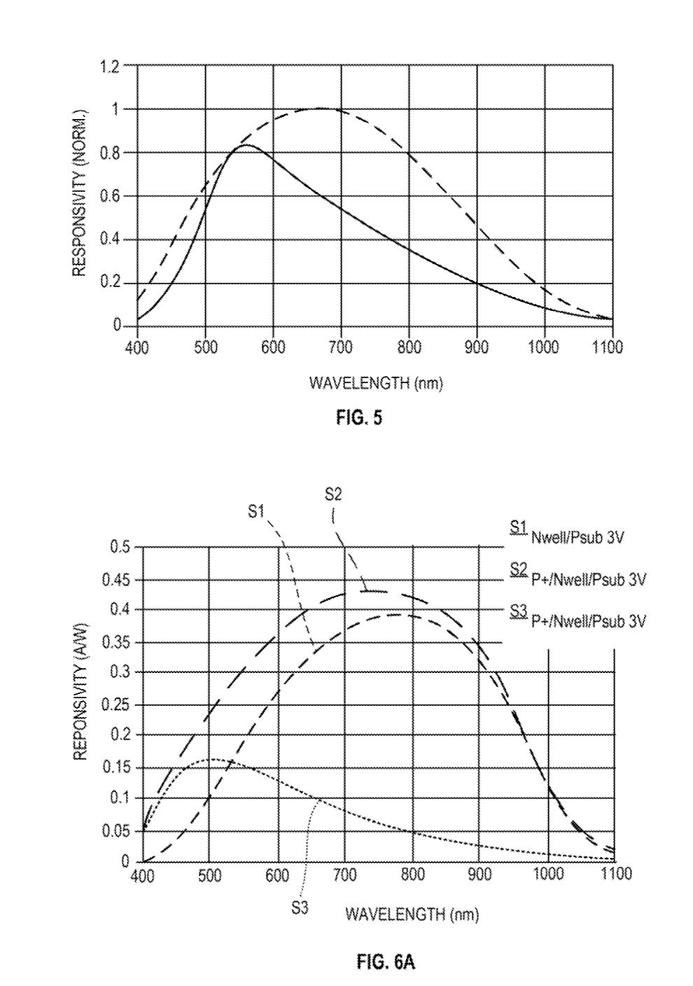

FIG. 5 shows the responsivity patterns obtained by simulation of a sensor 10 comprising a photodiode equipped with an anti-reflection coating composed only of an oxide being as thick as approximately 2000 A (broken curve) or of a double-layer anti-reflection coating comprising an oxide-nitride pair as above described (unbroken curve). In particular, the sensor 10 has been realized in the BCD3 technology.

It may be observed that the double-layer anti-reflection coating serves as a filter for the ultraviolet component (UV) and it considerably shifts the responsivity peak to the desired wavelength, in the case being concerned equal to approximately 540 nm and corresponding to the human eye response peak.

Conveniently, the thicknesses of such first and second anti-reflection layers 14 and 15 may be chosen according to the following table:

TABLE I

| Layer | λ = 540 nm |
|---|---|
| Thickness of SiO₂ = λ/2n | Approximately 190 nm |
| (n = 1.45) | |
| Thickness of Si₃N₄ = λ/4n | Approximately 70 nm |
| (n = 2) | |

(n is the approximate index of refraction of the indicated materials)

For a standard photodiode, although using such a double anti-reflection layer, the responsivity curve remains considerably far from the typical human eye response, and in particular it has a peak usually set at approximately 750-800 nm, this shifting not being sufficient for some applications of the sensor 10, like for example for its use as an ambient light sensor.

In order to improve this feature, according to an embodiment of the disclosure anti-reflection layers have thus been integrated on a sensor 10 comprising a vertical double-junction photodiode PHD, as shown in FIG. 3.

In this case, by conveniently biasing the vertical double-junction photodiode PHD it is possible to distinguish the photocurrents of single junctions (P+/Nwell and Nwell/Psub) and also to acquire the photocurrent deriving from the contribution of both junctions (P+/Nwell/Psub).

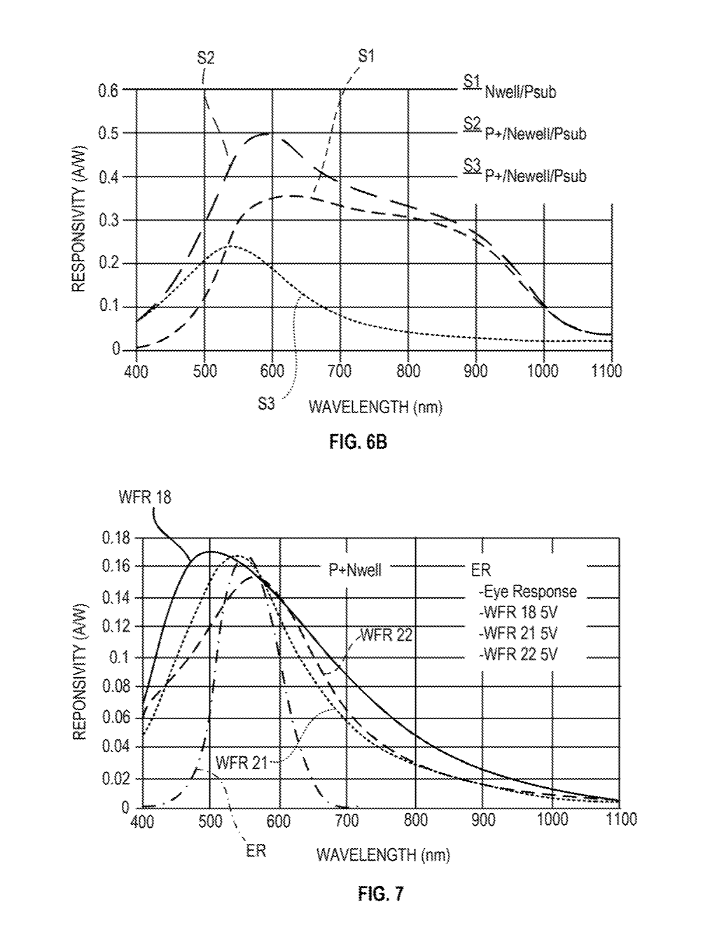

Sensors 10 have been realized by means of p-n junctions in the HCMOS4TZ technology. Examples of the responsivity curves are shown in FIGS. 6A e 6B.

In particular, FIG. 6A shows the responsivity curves of three different junctions, of the N+/Pwell, Nwell/Pwell and P+/Nwell type respectively, comprising a silicon oxide layer being as thick as approximately 1000 A as an anti-reflection layer, while FIG. 6B shows the responsivity curves concerning the same junctions, but comprising in this case a double-layer anti-reflection coating (SiO2/SiN). Data have been acquired in the same biasing configurations of these junctions.

It may be observed that the responsivity curve of simulated junctions changes if the double-layer anti-reflection coating is present and in an evident way. In particular, the anti-reflection layer composed of the silicon oxide/nitride pair keeps the above-indicated features and it shifts the responsivity peak from about 740 nm to about 540 nm.

The curves shown in FIG. 6B differ from the one of FIG. 5 since they are related to considerably different sensors, although the above-indicated shifting of the responsivity peak has been verified once again.

The sensor 10 with vertical double-junction photodiode PHD may have the advantage of allowing the diffusion current to be distinguished and eventually removed by means of the substrate, giving a considerable contribution to the responsivity spectrum in the near infrared region.

In particular, by displaying only the surface junction photocurrent a narrow spectrum is observed and, due to the double anti-reflection layer, with an approximately 540 nm peak.

FIG. 7 shows the responsivity curves related only to the surface junction in an embodiment of a vertical double-junction photodiode PHD with different anti-reflection layers and particularly:

WFR 18=anti-reflection oxide
WFR 21=anti-reflection oxide+tuning nitride
WFR 22=anti-reflection oxide+out-of-tuning nitride.

It may be observed that the curve WFR 21, related to the anti-reflection oxide+tuning nitride, proves to be the closest to the human eye response (curve ER).

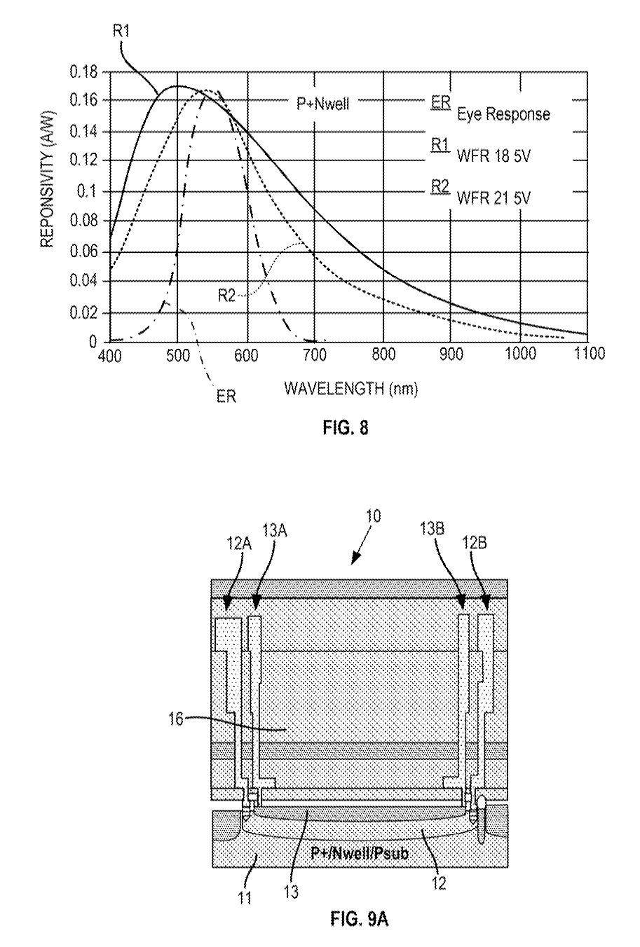

FIG. 8 shows in compared experimental data concerning the responsivity curve of a surface junction in the vertical double-junction photodiode PHD only having the oxide as anti-reflection layer or having oxide and nitride as a double anti-reflection layer.

An embodiment of the present disclosure also relates to an integration process of a sensor 10 of the above-indicated type. In particular, according to an embodiment of the disclosure the process comprises an integration step of the first and second anti-reflection layers of the sensor only at the end of the wafer manufacturing steps wherein the sensor is formed.

As it will be clear in the following description, an embodiment of the integration step of anti-reflection layers comprises low-thermal-budget depositions and it does not impact on the technology being used. Moreover, although in the following description reference will be made to a sensor 10 comprising a vertical double-junction photodiode, the process according to an embodiment of the disclosure may be used for any type of sensor, for example comprising pin diodes, transistors and the like.

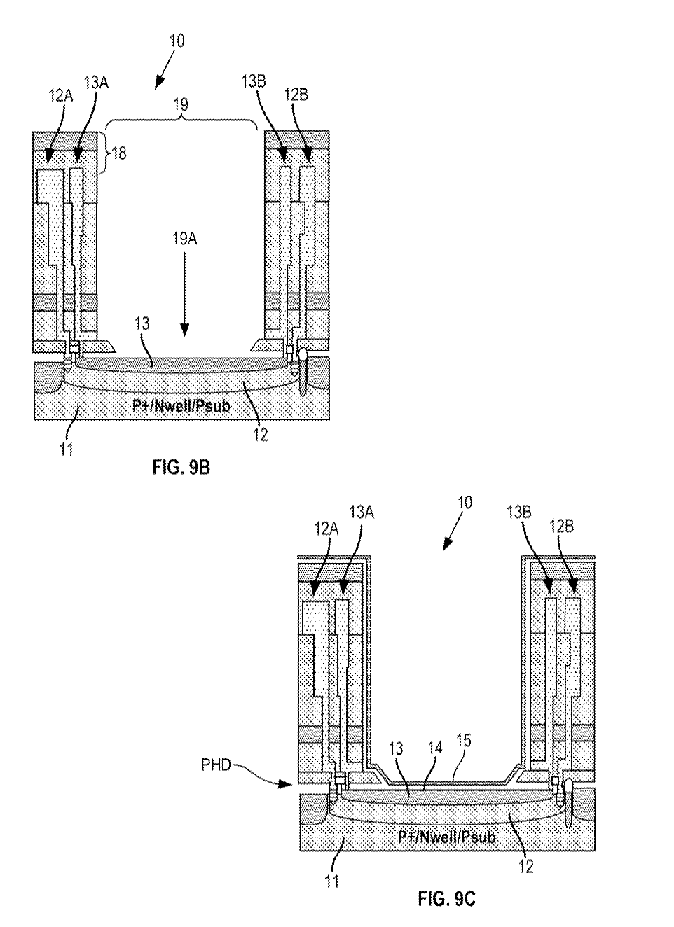

An embodiment of the integration process of the sensor 10 is shown hereinafter with reference to FIGS. 9A to 9D.

The process steps described hereinafter do not form a complete process flow for manufacturing integrated circuits. An embodiment of the present disclosure may be implemented together with the techniques for manufacturing integrated circuits presently used in the field and only those commonly used process steps being necessary for understanding are included.

Moreover, the drawings representing schematic views of portions of an integrated circuit during manufacturing may not be drawn to scale, but may be drawn on the contrary in order to emphasize main features of an embodiment of the disclosure.

In particular, as shown in FIG. 9A, the integration process of the sensor 10 in a multilayer structure comprising a semiconductor substrate 11 and an alternate structure of intermetal dielectric layers 16, as well as an upper passivation layer 18 according to an embodiment of the disclosure comprises the steps of:

forming in the semiconductor substrate 11 at least one first and one second pn junction, suitable to form at least one vertical double-junction photodiode PHD; and

forming contact structures for the electrical connection of the double junction in the alternate structure of intermetal dielectric layers 16.

Conveniently, due to the formation of contact structures for the double junction electrical connection, the active area of this double junction may be left as much as possible exposed by metallizations, so as to let, as far as possible, the electrical area coincide with the optical area of the sensor 10, the layers on this active area being the intermetal dielectric layers 16, as shown in FIG. 9A.

In particular, the integration process of the sensor 10 on a semiconductor substrate 11 according to an embodiment of the disclosure comprises the steps of:

forming in the semiconductor substrate 11 of a first doping type, for example of the P type, at least a well of a second doping type, for example of the N type; in particular, in the case shown in the figure, the N well 12 is formed; and

forming in the well an implant of the first doping type, for example of the P type; in particular, in the case shown in the figure, the implant of the P+ type 13 is formed.

In this way, the implant 13 of the P+ type and the N well 12 form a first junction, while the N well 12 and the semiconductor substrate 11 form a second junction of the vertical double-junction photodiode PHD.

According to an embodiment of the disclosure, the process then comprises a removal step of the intermetal dielectric layers 16 and of the upper passivation layer 18 in correspondence with an opening 19 formed in the intermetal dielectric layers 16 and suitable to expose a silicon surface 19A in correspondence with the double junction, as shown in FIG. 9B.

The intermetal dielectric 16 and upper passivation 18 layers are standard layers of silicon integration technologies.

In particular, this removal step of intermetal dielectric layers 16 and of the upper passivation layer 18 comprises an etching being chosen between a dry, wet or dry and wet etching.

In an embodiment, the removal step comprises a dry and wet etching allowing substantially vertical walls, i.e. substantially perpendicular to the surface 19A, to be obtained for the opening 19, this silicon surface 19A proving to be also less damaged if compared to an only-wet etching due to the combined presence of dry etching.

Furthermore, an embodiment of the process comprises a deposition step of the first anti-reflection dielectric layer 14 with a thickness of approximately λ/2n, being λ the wavelength equal to 540 nm corresponding to 1900 A, covering at least the surface 19A, as shown in FIG. 9C:

In particular, the first anti-reflection dielectric layer 14 may be made of silicon oxide.

According to an embodiment, the step of forming the opening 19 is designed so that most of the active area of the photodiode PHD double junction forming the sensor 10 is covered only by this first anti-reflection dielectric layer 14.

An embodiment then comprises a further deposition step of a second anti-reflection dielectric layer 15 with a thickness of approximately λ/4n, as shown in FIG. 9C.

In particular, the second anti-reflection dielectric layer 15 may be made of silicon nitride.

The process may then be completed by an etching step, being traditional in itself, of anti-reflection dielectric layers 14 and 15 and of the upper passivation layer 18 in correspondence with contact structures, in order to form appropriate connection openings to these contact structures.

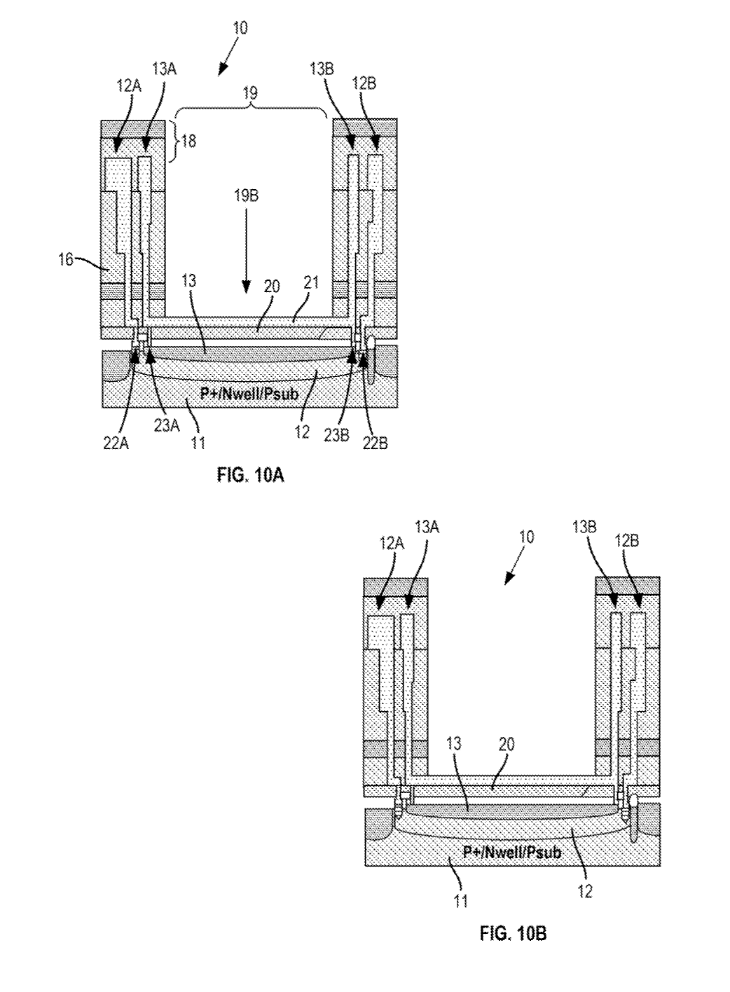

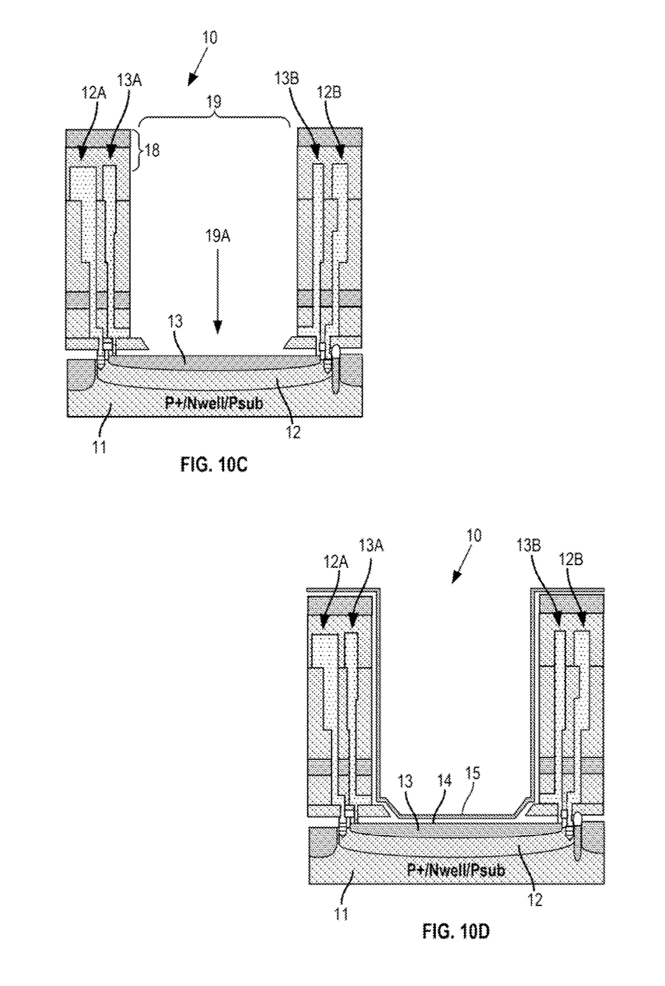

Referring now to FIGS. 10A to 10D, a second embodiment of a process is described.

In particular, in this embodiment, the removal step of the intermetal dielectric layers 16 and of the upper passivation layer 18 in correspondence with an opening 19 uses a layer 21 deposited on a first dielectric layer 20 as a stopping layer.

The process then comprises a removal step of the intermetal dielectric layers 16 and of the upper passivation layer 18 in correspondence with an opening 19 formed in these intermetal dielectric layers 16 and suitable to expose a surface 19B of the stopping layer 21 in correspondence with the implant 13 of the P+ type, as shown in FIG. 10A.

Conveniently, this removal step of the intermetal dielectric layers 16 and of the upper passivation layer 18 may comprise a dry etching using the layer 21 as a stopping layer, this stopping layer 21 thus completely covering the active area of the sensor 10.

Then a further dry etching step of the stopping layer 21 is performed to remove it without size losses, as schematically shown in FIG. 10B, as well as a wet etching step of the first underlying dielectric layer 20, so as not to compromise the underlying silicon layer surface and suitable to expose the silicon surface 19A in correspondence with the double junction of the vertical double-junction photodiode PHD, as shown in FIG. 10C.

Furthermore, an embodiment of the comprises a deposition step of the first anti-reflection dielectric layer 14 with a thickness of approximately 212 and of the second anti-reflection dielectric layer 15 with a thickness of approximately λ/4, as shown in FIG. 10D.

The presence of two anti-reflection layers allow a responsivity to be obtained, having a peak close to 540 nm, i.e. close to the human eye response (curve ER), as already schematically shown in FIG. 8.

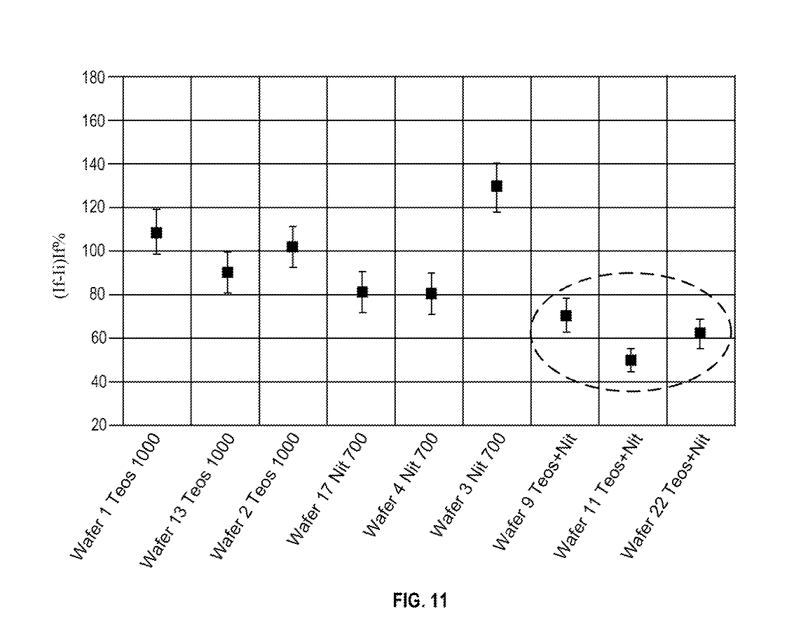

FIG. 11 shows the percent error between the photocurrent obtained by lighting up a sensor 10 formed according to an embodiment of the disclosure by means of a fluorescent lamp and an incandescent lamp respectively. This error thus indicates the effectiveness of such a sensor used as an ambient light sensor and it thus indicates how the responsivity resembles the human eye response.

In particular, the measures quoted in the figures are related to different wafers belonging to different batches for the single junctions being in a photodiode having the stacked configuration (P+/Nwell and NWell/Psub), as well as for the total of these junctions (P+/Nwell/Psub).

From FIG. 11 it may be deduced that the percent error for the surface junction in a vertical double-junction photodiode PHD with a double anti-reflection layer comprising oxide and nitride as an anti-reflection layer, indicated with a circle in the figure, proves to be the lowest, this combination of stacked configuration and double anti-reflection layer proving to be actually one of the best choices to form an ambient light sensor.

An embodiment of the present disclosure also relates to an ambient light sensor or ALS formed by the sensor 10 as above described.

In fact, as above indicated, the sensor according to the disclosure allows an ambient light sensor to be formed, having a responsivity curve close to the human eye one.

According to an embodiment of the disclosure, this responsivity curve shifting is obtained by using a vertical double-junction photodiode structure whereon at least a double-layer coating is deposited, for example comprising a silicon oxide-nitride pair.

A sensor according to an embodiment of the disclosure may have the same base structure as the sensors formed according to the prior art, thus allowing a considerable saving in terms of investments from the technological point of view.

Furthermore, such a sensor may be completely formed of silicon and the process according to an embodiment of the disclosure may be easily integrated in any technology.

A further advantage of the sensor 10 according to an embodiment of the disclosure is the possibility, due to the vertical double-junction formed by the substrate, well and implant, to distinguish and in case remove the diffusion photocurrent by means of the substrate itself, representing a considerable contribution to the responsivity spectrum in the near infrared (IR) region, thus removing an undesired component particularly in the case of applications as an ambient light sensor.

In particular, the use of a double-layer anti-reflection coating allows the photodiode responsivity curve to be deeply changed. It is also possible, by conveniently designing this double-layer anti-reflection coating, to use it as a filter for the ultraviolet component (UV), considerably shifting the responsivity peak to the desired wavelength, in particular corresponding to approximately 540 nm.

A further advantage of the sensor and process according to an embodiment of the disclosure is the fact that the integration step of anti-reflection layers for the photodiodes may occur at the end of the manufacturing process of the wafer comprising the sensor itself. Moreover, since dealing with depositions not involving high thermal budgets, the integration of these anti-reflection layers may not impact on the technology being used.

Also, a sensor according to an embodiment of the disclosure may allow an effective single-photodiode ambient light sensor to be formed, with a limited area occupation and cost, due to the fact that it does not require a particular package to be developed.

One skilled in the art, in order to meet contingent and specific requirements, could bring several changes and variations to the above-described sensor and integration process, all falling within the spirit and scope of protection of the disclosure.

Also, one or more embodiments of the anti-reflection double layer as above described with reference to the sensor application as an ambient light sensor may be extended to other radiation sensors, particularly in the silicon absorption region.

Furthermore, an embodiment of the above-described sensor may be disposed in an integrated circuit of that is coupled to another integrated circuit to form a system. These integrated circuits may be formed on the same or on different dies.

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

1-34. (canceled)

35. A method, comprising:
receiving a wavelength of electromagnetic radiation through a first material having a first thickness approximately equal to one fourth of the wavelength and through a second material having a second thickness approximately equal to one half of the wavelength; and
generating a first current across a first p-n junction in response to the received wavelength; and
generating a second current across a second p-n junction in response to the received wavelength.

36. The method of claim 35 wherein the first p-n junction is disposed over the second p-n junction.

37. The method of claim 35 wherein the first material is disposed over the second material.

38. The method of claim 35, further comprising combining the first and second currents.

39. The method of claim 35, further comprising summing the first and second currents.

40. The method of claim 35, further comprising subtracting one of the first and second currents from the other of the first and second currents.

41. The method of claim 35, further comprising adjusting a brightness of an apparatus in response to at least one of the first and second currents.

42. A method, comprising:
receiving electromagnetic radiation at a first junction and at a second junction disposed under the first junction;
generating a first signal having a first magnitude corresponding to the electromagnetic radiation received at the first junction; and
generating a second signal having a different magnitude corresponding to the electromagnetic radiation received at the second junction.

43. The method of claim 42, further comprising combining the first and second signals.

44. The method of claim 42, further comprising summing the first and second signals.

45. The method of claim 42, further comprising subtracting one of the first and second signals from the other of the first and second signals.
